(19) United States
(12) Patent Application Publication
(10) Pub. No.: US 2004/0026741 A1
(43) Pub. Date: Feb. 12, 2004

(54) Semiconductor integrated circuit device

(75) Inventors: Noriaki Saito, Kawasaki (JP); Katsuaki Aizawa, Kawasaki (JP); Kazuhiro Kitani, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 10/633,544

(22) Filed: Aug. 5, 2003

(30) Foreign Application Priority Data
Aug. 8, 2002 (JP) 2002-232096

(51) Int. Cl. H01L 23/62

(52) U.S. Cl. 257/355

(57) ABSTRACT

In a semiconductor integrated circuit device, an n-channel transistor area has an area A on a pad side and an area B on an internal circuit side, where a plurality of protective elements are connected in parallel between a signal line and a power supply line. Each of the protective elements has resistors. Resistance of the resistors in the area A is set higher than resistance of the resistors in the area B by a value corresponding to resistance of parasitic resistance of the signal line included in the area A so that the resistance of the protective elements in the areas A and B are the same or almost the same as each other. A p-channel transistor area has the same configuration as that of the p-channel transistor area.

### CROSS-REFERENCE TO RELATED APPLICATIONS

This application is based upon and claims the benefit of priority from the prior Japanese Patent Application No.2002-232096, filed on Aug. 8, 2002, the entire contents of which are incorporated herein by reference.

### BACKGROUND OF THE INVENTION

1) Field of the Invention

The present invention relates to a semiconductor integrated circuit device provided with protective elements that protect metal oxide semiconductor (MOS) transistors against an electrostatic breakdown.

2) Description of the Related Art

Generally, an integrated circuit formed with a complementary metal oxide semiconductor (CMOS) integrated circuit has protective elements provided to protect an input-output (I/O) circuit against an electrostatic breakdown. Therefore, when the protective elements are formed with MOS transistors, it is necessary to prevent a breakdown of the protective elements due to static electricity.

Conventionally, a narrow pitch I/O circuit is known as an I/O circuit for a semiconductor integrated circuit. The narrow pitch I/O circuit is obtained by disposing a plurality of transistors in the I/O circuit in advance and changing layout of wirings that connect the transistors as required. By changing the layout, an I/O circuit with desired configuration and features is manufactured. FIG. 1 shows a circuit diagram of the configuration of a conventional protective circuit applied to such a narrow pitch I/O circuit.

As shown in FIG. 1, a signal line 3 establishes a connection between a pad 1 and an internal circuit 2. A plurality of p-channel MOS transistors PT₁, PT₂, . . . , PTₙ are connected in parallel between the signal line 3 and a power supply voltage VDD of relatively high electric potential level. Further, a plurality of resistors 4 are connected between respective drains of these transistors and the signal line 3. A plurality of n-channel MOS transistors NT₁, NT₂, . . . , NTₙ are connected in parallel between the signal line 3 and a power supply voltage VSS of relatively low electric potential level. A plurality of resistors 5 are connected between respective drains of these transistors and the signal line 3.

FIG. 2 is a layout of elements that form the conventional protective circuit shown in FIG. 1. In the configuration of FIG. 2, the signal line 3 is indicated by a phantom line (a two-dot line). A p-channel transistor area 6 consists of the p-channel MOS transistors PT₁, . . . , PTₙ₋₁, PTₙ, and the respective resistors 4 in the p-channel transistor area 6 are provided with silicide blocks 7 that are formed on the drain side of the transistors, respectively. Likewise, an n-channel transistor area 8 consists of the n-channel MOS transistors NT₁, . . . , NTₙ₋₁, NTₙ, and the respective resistors 5 in the n-channel transistor area 8 are provided with silicide blocks 9 that are formed on the drain side of the transistors, respectively.

However, in the conventional circuit shown in FIG. 1, there are problems as follows caused by a parasitic resistance of the signal line 3. As shown in FIG. 3, point A is set at a point near pad 1 of the signal line 3, point C is set at a point on a boundary between the n-channel transistor area 8 and the p-channel transistor area 6, and point B is set at an intermediate point between the points A and C on the signal line 3. The area between the point A and the point B is referred to as area A and the area between the point B and the point C is referred to as area B. The area B is in a state where a parasitic resistance (rAB) from the point A to the point B is added. Therefore, the resistors 5 of resistance r are connected between the drains of the transistors NTₘ₊₁, . . . , NTₙ and the signal line 3 in the area B, but, actually, the connected resistors 5 have resistance r+rAB.

On the other hand, the resistors 5 connected between the drains of the transistors NT₁, . . . , NTₘ and the signal line 3 in the area A have only resistance r. Therefore, when electrostatic discharge (ESD) is excessively input from the pad 1, the resistance of the resistors 5 in the area A seems lesser than that of the area B. As a result, the transistors NT₁, . . . , NTₘ in the area A are easily destroyed due to the concentration of current. Likewise, the transistors of the p-channel transistor area 6 near the pad 1 are easily destroyed due to the same cause as explained above. In other words, the signal line 3 has the parasitic resistance and therefore the ESD load is unevenly applied to the transistors of the protective circuit. Consequently, any of the transistors applied with the maximum ESD load is destroyed.

### SUMMARY OF THE INVENTION

It is an object of the present invention to provide a semiconductor integrated circuit device with protective elements that protect MOS transistors against electrostatic breakdown in which protective transistors for internal circuits are protected against breakdown by uniformly distributing ESD load to the protective elements in the protective circuit.

In order to achieve the object, the present invention is provided by taking parasitic resistance of a signal line connecting a pad to internal circuits into consideration. The present invention is characterized in that the resistance of the protective elements connected in parallel between the signal line and a power supply line is gradually reduced from the pad toward the internal circuits. According to the present invention, the protective elements have the same or almost the same resistance as each other, and therefore the ESD load is evenly applied to the protective transistors for the internal circuits in the protective elements.

The other objects, features and advantages of the present invention are specifically set forth in or will become apparent from the following detailed descriptions of the invention when read in conjunction with the accompanying drawings.

### BRIEF DESCRIPTION OF THE DRAWINGS

FIG. 1 shows a circuit diagram of the configuration of a protective circuit applied to a conventional I/O circuit;

FIG. 2 shows a layout of elements of the protective circuit applied to the conventional I/O circuit;

FIG. 3 shows a partial configuration of the protective circuit applied to the conventional I/O circuit;

FIG. 4 shows a circuit diagram of a partial configuration of a protective circuit in the semiconductor integrated circuit device according to a first embodiment of the present invention;

FIG. 5 shows the comparison of sizes of silicide blocks in area A and area B of an n-channel transistor area in the semiconductor integrated circuit device shown in FIG. 4;

FIG. 6 shows a layout of a partial configuration of elements in an example in which resistors in the protective circuit of the semiconductor integrated circuit device shown in FIG. 4 are formed by silicide resistors;

FIG. 7 shows the comparison of sizes of silicide resistors in the area A and the area B of the n-channel transistor area;

FIG. 8 shows a circuit diagram of a partial configuration of a protective circuit in the semiconductor integrated circuit device according to a second embodiment of the present invention;

FIG. 9 shows a layout of a partial configuration of elements in an example in which resistors in the protective circuit of the semiconductor integrated circuit device shown in FIG. 8 are formed by silicide blocks and silicide resistors;

FIG. 10 shows the comparison of sizes of silicide resistors in the area A and the area B of the n-channel transistor area in the semiconductor integrated circuit device shown in FIG. 8; and

FIG. 11 shows a layout of a partial configuration of elements in an example in which resistors in the protective circuit of the semiconductor integrated circuit device shown in FIG. 8 are formed by silicide blocks and drain wiring.

### DETAILED DESCRIPTION

Exemplary embodiments of the present invention are explained in detail below with reference to the accompanying drawings.

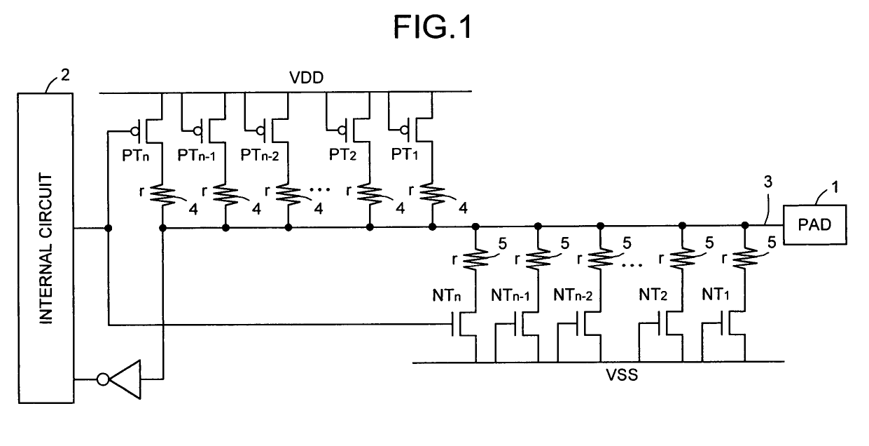

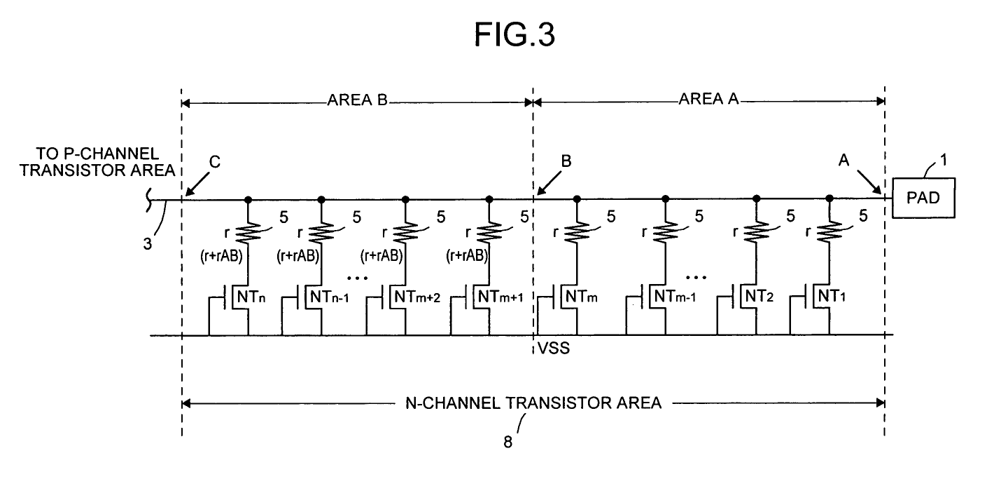

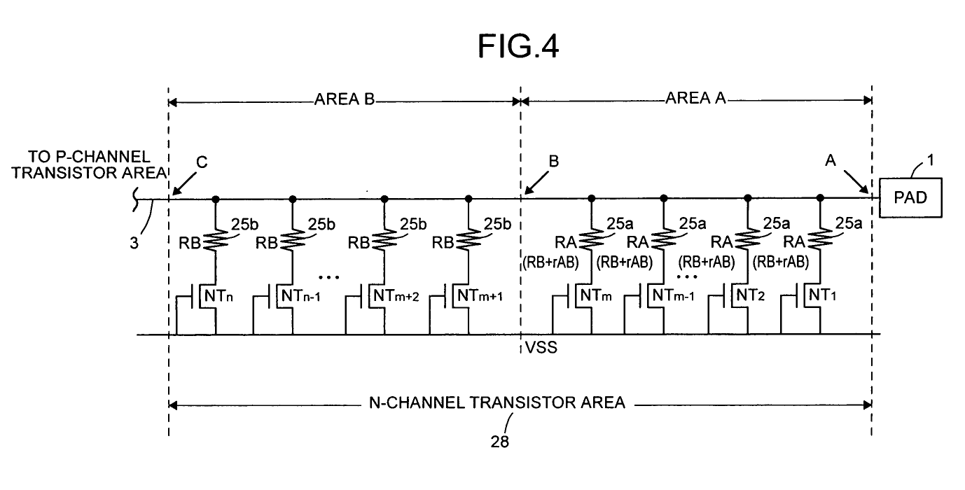

FIG. 4 shows a circuit diagram of a partial configuration of a protective circuit in the semiconductor integrated circuit device according to a first embodiment of the present invention. FIG. 4 shows only a part, i.e., an n-channel transistor area corresponding to the conventional configuration shown in FIG. 3, and the entire circuit configuration according to the first embodiment is similar to the conventional circuit shown in FIG. 1 though not shown in particular. Hence explanations of the parts will be omitted to avoid repetition of explanation.

As shown in FIG. 4, in the n-channel transistor area 28, resistors 25a of the area A has resistance of RA, and resistors 25b of the area B has resistance of RB. The resistance RA is higher than the resistance RB by resistance rAB of parasitic resistance between the point A and the point B of the signal line 3, that is, RA=RB+rAB. In other words, the resistance RB is lower than the resistance RA by the resistance rAB, that is, RB=RA−rAB.

Since explanations of the points A, B, and C and the areas A and B have already been given in FIG. 3, the explanations of the same will be omitted here. Further, the p-channel transistor area (not shown) is provided between the n-channel transistor area 28 and the internal circuit (not shown) like in the conventional configuration. The p-channel transistor area is divided into, for example, two areas like in the n-channel transistor area as one area (“pad area”) on the side of the pad 1 and the other area (“internal circuit area”) on the side of the internal circuit. The resistance of the resistors in the pad area is larger than that of the resistors in the internal circuit area by the parasitic resistance of the signal line 3.

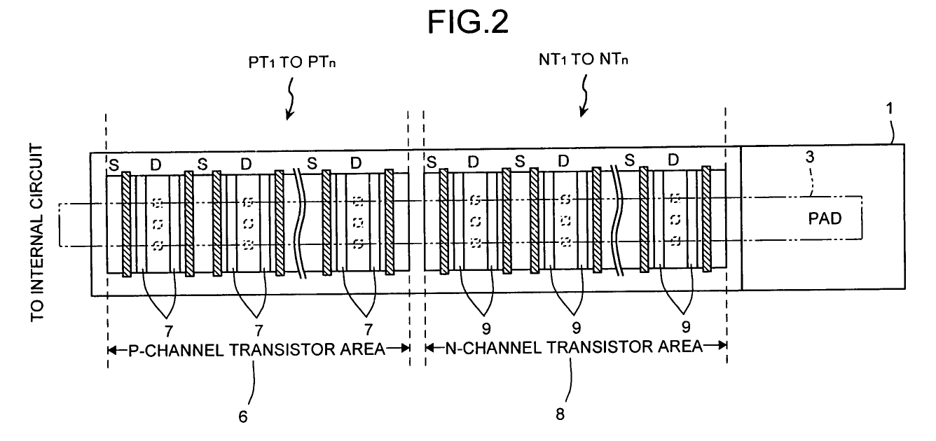

The resistors 25a connected to the drains of the protective transistors for the internal circuit NT₁ to NRₘ in the area A are provided with silicide blocks formed on the drain side of the transistors. Similarly, the resistors 25b connected to the drains of the protective transistors for the internal circuit NTₘ₊₁ to NTₙ in the area B are also provided with the silicide blocks formed on the drain side of the transistors. The silicide blocks correspond to the area where a silicide layer converting the resistance to low resistance is not formed on the semiconductor substrate. Further, the layout of the elements forming the n-channel transistor area 28 and the p-channel transistor area (not shown) is similar to that of the conventional circuit shown in FIG. 2. However, the size of the silicide blocks of the area A in the n-channel transistor area 28 differs from that of the silicide blocks of the area B therein. Moreover, in the p-channel transistor area, the size of the silicide blocks in the pad area differs from that of the silicide blocks in the internal circuit area.

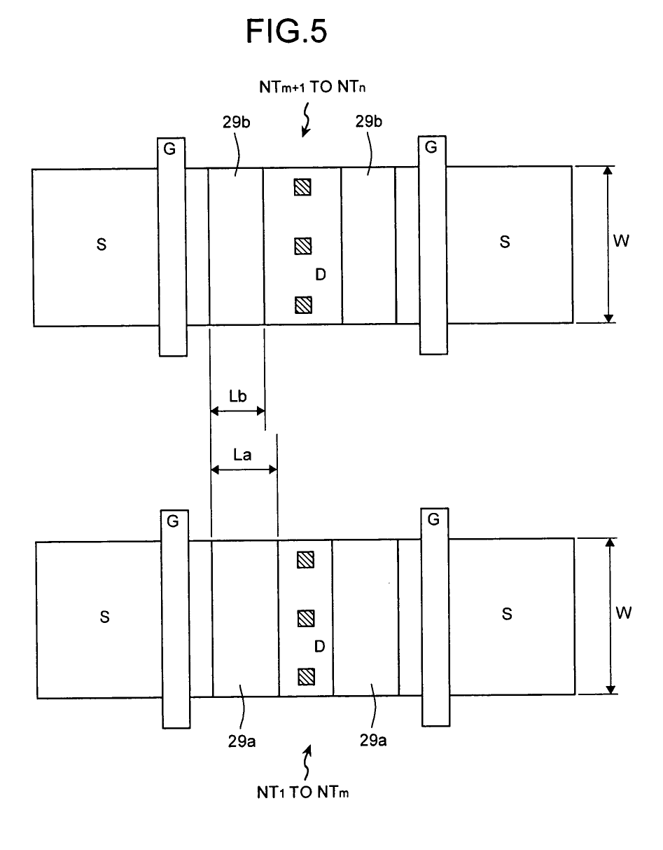

FIG. 5 shows the comparison of the sizes of the silicide blocks between the area A and the area B in the n-channel transistor area 28. As shown in FIG. 5, the length La of silicide block 29a in the area A (the lower part of the figure) is higher than the length Lb of silicide block 29b in the area B (the upper part of the figure). The difference between the two lengths corresponds to the parasitic resistance rAB of the signal line 3 from the point A to the point B. The width of the silicide block 29a in the area A is the same as the width of the silicide block 29b in the area B and the width is indicated by W. In FIG. 5 and the other figures, a source area, a drain area, and a gate electrode of the transistors are indicated by S, D, and G, respectively.

The p-channel transistor area (not shown) has a configuration similar to that of the n-channel transistor. That is, the width of the silicide block in the pad area is the same as the width of the silicide block in the internal circuit area. However, the length of the silicide block in the pad area is higher than the length of the silicide block in the internal circuit area by a portion corresponding to the parasitic resistance of the signal line 3.

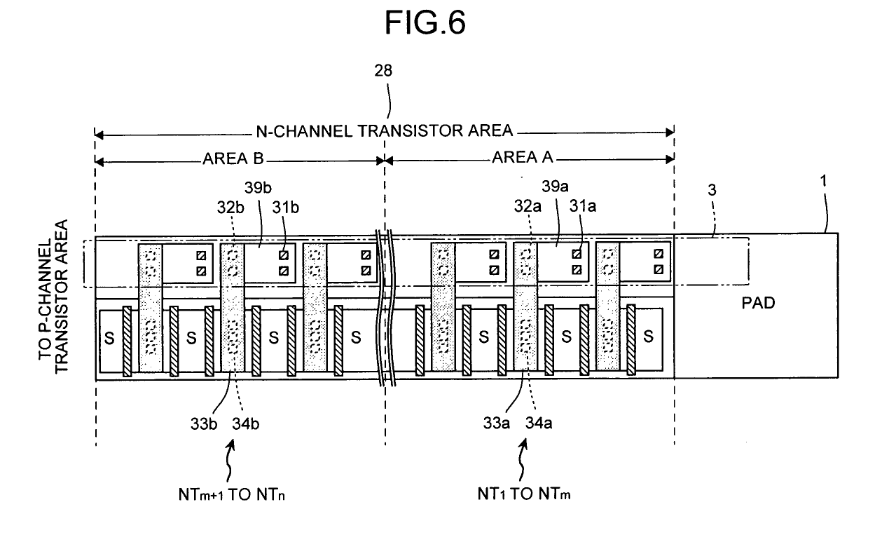

As shown in FIG. 6, the resistors 25a in the area A and the resistors 25b in the area B may be formed with a plurality of silicide resistors 39a and 39b, respectively. The silicide resistors 39a and 39b are formed beneath the signal line 3 and one ends of the silicide resistors 39a and 39b are electrically connected to the signal line 3 through contacts 31a and 31b respectively. The other ends of the suicide resistors 39a and 39b are electrically connected to drain wirings 33a and 33b through contacts 32a and 32b, respectively. Further, the drain wiring 33a in the area A is electrically connected to the drain area of the respective MOS transistors through a contact 34a. Similarly, the drain wiring 33b in the area B is electrically connected to the drain area of the respective MOS transistors through a contact 34b.

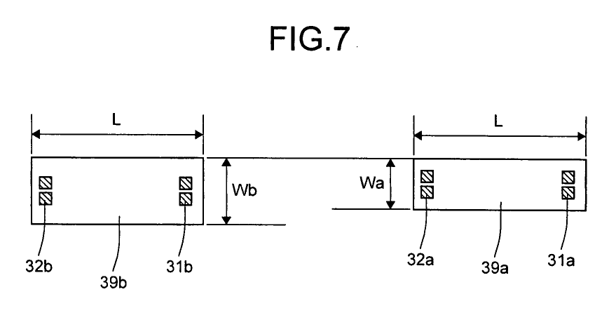

The area A and the area B of the n-channel transistor area 28 are different from each other in the size of the silicide resistors 39a and 39b. Similarly, in the p-channel transistor area, the size of the silicide resistors in the pad area differs from the size of the silicide resistors in the internal circuit area. FIG. 7 shows the comparison of the sizes of the silicide resistors 39a and 39b between the area A and the area B of the n-channel transistor area 28. As shown in FIG. 7, the width Wa of the silicide resistor 39a in the area A (right-hand side in the figure) is lesser than the width Wb of the silicide resistor 39b in the area B (left-hand side in the figure). The difference between the two widths corresponds to the parasitic resistance rAB of the signal line 3 from point A to point B (see FIG. 4). The length La of the silicide resistor 39a in the area A is the same as the length Lb of the silicide resistor 39b in the area B.

The configuration of the p-channel transistor area (not shown) is similar to that of the n-channel transistor area 28. That is, the length of the silicide resistor in the pad area is the same as the length of the silicide resistor in the internal circuit area. However, the width of the silicide block in the pad area is larger than the width of the silicide block in the internal circuit area by a portion corresponding to the parasitic resistance of the signal line 3.

According to the first embodiment, the ESD load applied to the protective transistors for the internal circuit in each of the protective elements becomes uniform, since the resistance of the protective elements connected in parallel to the signal line 3 connecting the pad 1 to the internal circuit is the same or almost the same as each other. Therefore, the load due to the excessive input of the ESD is distributed over the protective transistors for the internal circuit. In this manner, it is possible to control the early breakdown of any of the protective transistors during excessive input of ESD or the like, thus enhancing protection of the internal circuits.

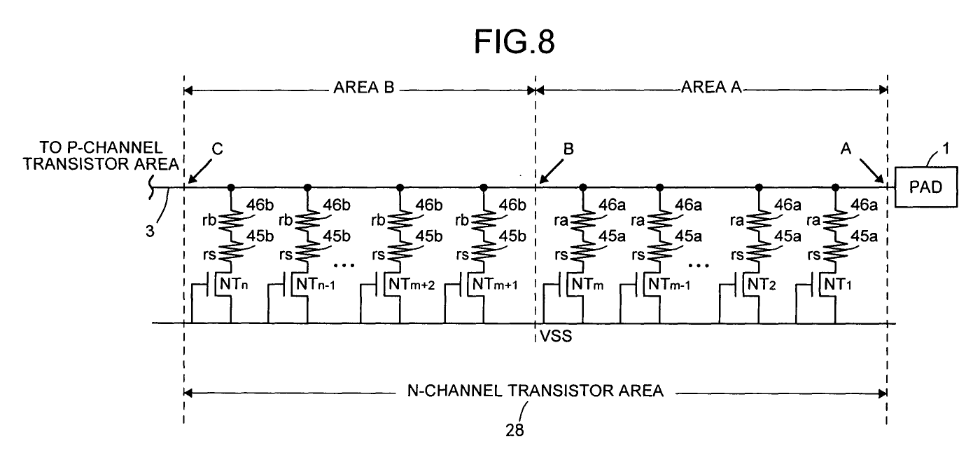

FIG. 8 shows a circuit diagram of a partial configuration of a protective circuit in the semiconductor integrated circuit device according to a second embodiment of the present invention. FIG. 8 shows only a part, i.e., the n-channel transistor area corresponding to the conventional configuration as shown in FIG. 3. The second embodiment differs from the first embodiment of FIG. 4 in that resistors (25a and 25b in the first embodiment) in each of the protective elements are formed with serially connected suicide blocks and the silicide resistors, respectively. The rest part of the configuration is the same as that of the first embodiment and therefore explanation of the rest part will be omitted.

In the n-channel transistor area 28, the resistance rs of resistors 45a formed by silicide blocks in the area A is the same as the resistance rs of resistors 45b formed by silicide blocks in the area B. In addition, the resistance ra of resistors 46a formed by silicide blocks in the area A is higher than the resistance rb of resistors 46b in the area B by a resistance rAB of the parasitic resistance of the signal line 3 from the point A to the point B, that is, ra=rb+rAB. In other words, rb is lower than ra by rAB, that is, rb=ra−rAB. The same effect is obtained in the p-channel transistor area.

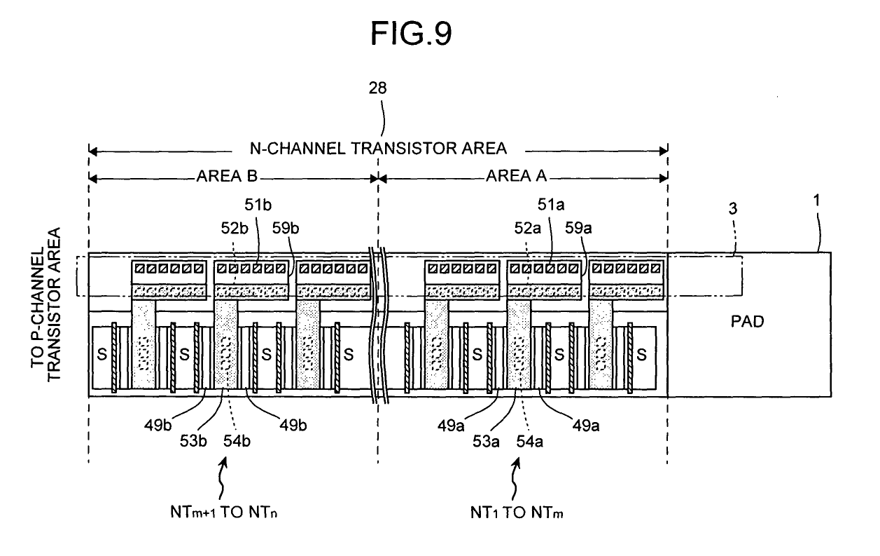

FIG. 9 shows a layout of the elements that form the protective circuit shown in FIG. 8. As shown in FIG. 9, silicide blocks 49a and 49b formed with the respective resistors 45a and 45b are formed on the drain side of the corresponding protective transistors for the internal circuit NT₁ to NTₙ as in the case of the example of the first embodiment (see FIG. 5). Further, the silicide blocks 49a in the area A and the silicide blocks 49b in the area B are of the same size.

The silicide resistors 59a and 59b forming the resistors 46a and 46b are electrically connected at one ends thereof to the signal line 3 through the contacts 51a and 51b, respectively. The other ends of the silicide resistors 59a and 59b are electrically connected to drain wirings 53a and 53b through contacts 52a and 52b, respectively. The drain wiring 53a in the area A is electrically connected to the drain area of the MOS transistors in the area A through contacts 54a. Further, the drain wiring 53b in the area B is electrically connected to the drain area of the MOS transistors in the area B through contacts 54b.

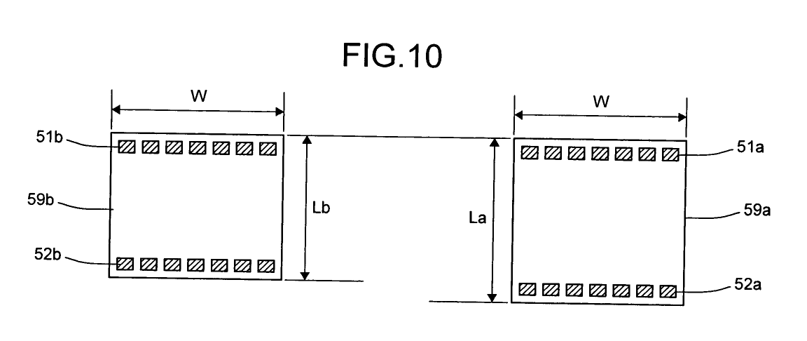

FIG. 10 shows the comparison of the sizes of the silicide resistors 59a and 59b. As shown in FIG. 10, the length La of the silicide resistor 59a (the right-hand side of FIG. 10) is higher than the length Lb of the silicide resistor 59b (the left-hand side of FIG. 10) by a value corresponding to the resistance rAB of the parasitic resistance of the signal line 3 from the point A to the point B. However, the width W of the silicide resistor 59a in the area A is the same as the width W of the silicide resistor 59b in the area B. Similarly, the p-channel transistor area (not shown) has the same configuration as that of the n-channel transistor area.

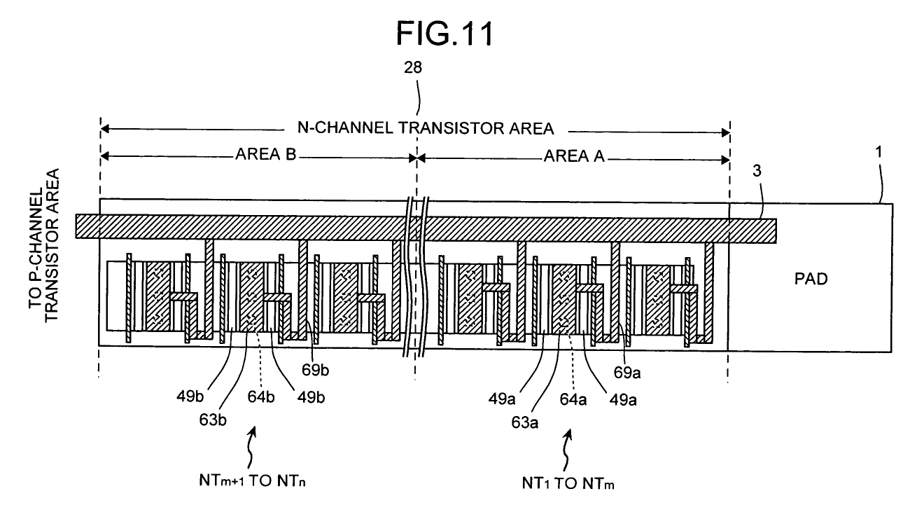

As shown in FIG. 11, the resistors in each of the protective elements may be formed with the silicide blocks 49a, 49b and the drain wirings 69a, 69b that connect the drain electrodes 63a, 63b to the signal line 3, respectively. In the area A, the drain electrode 63a is electrically connected to the drain area of the MOS transistor through the contact 64a. Similarly, in the area B, the drain electrode 63b is electrically connected to the drain area of the MOS transistor through the contact 64b.

The silicide blocks 49a and 49b in the areas A and B are of the same size, and are formed on the drain side of the corresponding protective transistors for the internal circuit NT₁ to NTₙ. The drain wiring 69a in the area A is longer than the drain wiring 69b in the area B by a value corresponding to the parasitic resistance rAB of the signal line 3 from the point A to the point B. Similarly, the p-channel transistor area (not shown) has the same configuration as that of the n-channel transistor area.

According to the second embodiment, the ESD load applied to the protective transistors for the internal circuit in each of the protective elements becomes uniform as in the case of the first embodiment, and the load due to the excessive input of the ESD or the like is distributed to the protective transistors for the internal circuit. In this manner, it is possible to control the early breakdown of any of the protective transistors during excessive input of ESD or the like and therefore making it possible to enhance protection of the internal circuits.

The present invention may also have variations as it is not particularly limited to the explained embodiments. For example, resistors in the protective element having a combination of silicide blocks and silicide resistors may be provided such that the resistance of the silicide blocks is changeable or the resistance of both the suicide blocks and suicide resistors is changeable. Further, polysilicon resistors or well resistors may also be used as resistors in the protective element. In addition, the resistance of the resistors in the protective element may be changed by changing the width of the drain wiring connected to the signal line 3. Further, the resistance of the resistors in the protective element may be changed by altering the number of contacts that electrically connect the drain wiring connected to the signal line 3 to the drain area of the protective transistors for the internal circuit.

Moreover, resistance may be obtained by adaptively combining any of those among silicide blocks, silicide resistors, polysilicon resistors, well resistors, resistance of drain wiring, and resistance of the contact electrically connecting the drain wiring to the drain area. Further, although each of the n-channel transistor area and the p-channel transistor area is divided into two areas (A and B), the area may also be divided into three or more areas. By determining the n-channel transistor area as one area, respective resistance of the protective elements therein may be altered one by one. The p-channel transistor area has the same configuration as explained above. Therefore, respective resistance of the protective elements in the p-channel transistor area may be altered one by one by determining the p-channel transistor area as one area. Further, the present invention is also applicable to any I/O circuits other than the narrow pitch I/O circuit.

According to the present invention, since the resistance of the plurality of resistors connected in parallel between the signal line connecting the pad to the internal circuit and the power supply line is the same or almost the same, the ESD load applied to the protective transistors for the internal circuit in each of the protective elements becomes uniform. Therefore, the load is evenly distributed to the protective transistors even during excessive input of ESD or the like, and therefore it is possible to prevent the destruction of a part of the protective transistors for the internal circuit.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor integrated circuit device comprising:
a protective circuit including
a plurality of protective elements connected in parallel between a signal line and a power supply line, each including
a plurality of metal oxide semiconductor (MOS) transistors, and
a plurality of resistors, wherein, in the respective protective elements, drains of the MOS transistors are connected to the signal line that establishes a connection between a pad and an internal circuit through the resistors, and sources of the MOS transistors are connected to the power supply line,
wherein a resistance of the resistors in each of the protective elements is gradually decreased from the pad toward the internal circuit.

2. The semiconductor integrated circuit device according to claim 1, wherein the resistance of the resistors becomes lower from the pad toward the internal circuit according to a parasitic resistance of the signal line.

3. The semiconductor integrated circuit device according to claim 1, wherein the resistors are polysilicon resistors formed on a semiconductor substrate.

4. The semiconductor integrated circuit device according to claim 1, wherein the resistors are well resistors formed on a semiconductor substrate.

5. The semiconductor integrated circuit device according to claim 1, wherein the resistors are suicide resistors formed on a semiconductor substrate.

6. The semiconductor integrated circuit device according to claim 1, wherein the resistors are suicide blocks formed on a semiconductor substrate.

7. The semiconductor integrated circuit device according to claim 1, wherein the resistors are formed with elements whose resistance is changed by changing at least one of a length and a width of drain wiring connected to the signal line.

8. The semiconductor integrated circuit device according to claim 1, wherein the resistors are formed with elements whose resistance is changed by changing a number of contacts that establish electric connections between drain wirings connected to the signal line and a drain area.

9. The semiconductor integrated circuit device according to claim 1, wherein the resistors are elements each formed with a combination of at least two selected from a group consisting of a) polysilicon resistors, b) well resistors, c) silicide resistors, and d) silicide blocks.

10. The semiconductor integrated circuit device according to claim 1, wherein when decreasing the resistance of the resistors in each of the protective elements, the resistance is gradually decreased with at least every other unit among the resistors from the pad toward the internal circuit.

11. A semiconductor integrated circuit device comprising:
a narrow pitch input-output (I/O) circuit having a system of obtaining an I/O circuit with a desired configuration by changing wirings connecting a plurality of transistors disposed in the I/O circuit, the narrow pitch I/O circuit including
a protective circuit including
a plurality of protective elements connected in parallel between a signal line and a power supply line, each including
a plurality of metal oxide semiconductor (MOS) transistors, and
a plurality of resistors, wherein, in the respective protective elements, drains of the MOS transistors are connected to the signal line that establishes a connection between a pad and an internal circuit through the resistors, and sources of the MOS transistors are connected to the power supply line, wherein a resistance of the resistors in each of the protective elements is gradually decreased from the pad toward the internal circuit.

12. A semiconductor integrated circuit device comprising:
a protective circuit including
a plurality of protective elements connected in parallel between a signal line and a power supply line, each including
a plurality of metal oxide semiconductor (MOS) transistors, and
a plurality of resistors, wherein, in the respective protective elements, drains of the MOS transistors are connected to the signal line that establishes a connection between a pad and an internal circuit through the resistors, and sources of the MOS transistors are connected to the power supply line,
wherein a resistance of the resistors in each of the protective elements is lower than a resistance of resistors in a first adjacent protective element on a side of the pad, and is higher than a resistance of resistors in a second adjacent protective element on a side of the internal circuit.

13. The semiconductor integrated circuit device according to claim 12, wherein the resistance of the resistors becomes lower from the pad toward the internal circuit according to a parasitic resistance of the signal line.

14. The semiconductor integrated circuit device according to claim 12, wherein the resistors are polysilicon resistors formed on a semiconductor substrate.

15. The semiconductor integrated circuit device according to claim 12, wherein the resistors are well resistors formed on a semiconductor substrate.

16. The semiconductor integrated circuit device according to claim 12, wherein the resistors are silicide resistors formed on a semiconductor substrate.

17. The semiconductor integrated circuit device according to claim 12, wherein the resistors are suicide blocks formed on a semiconductor substrate.

18. The semiconductor integrated circuit device according to claim 12, wherein the resistors are formed with elements whose resistance is changed by changing at least one of a length and a width of drain wiring connected to the signal line.

19. The semiconductor integrated circuit device according to claim 12, wherein the resistors are formed with elements whose resistance is changed by changing a number of contacts that establish electric connections between drain wirings connected to the signal line and a drain area.

20. The semiconductor integrated circuit device according to claim 12, wherein the resistors are elements each formed with a combination of at least two among those: a) polysilicon resistors, b) well resistors, c) silicide resistors, and d) silicide blocks.

21. A semiconductor integrated circuit device comprising:
a narrow pitch input-output (I/O) circuit having a system of obtaining an 1/0 circuit with a desired configuration by changing wirings connecting a plurality of transistors disposed in the I/O circuit, the narrow pitch I/O circuit including
a protective circuit including
a plurality of protective elements connected in parallel between a signal line and a power supply line, each including
a plurality of metal oxide semiconductor (MOS) transistors, and
a plurality of resistors, wherein, in the respective protective elements, drains of the MOS transistors are connected to the signal line that establishes a connection between a pad and an internal circuit through the resistors, and sources of the MOS transistors are connected to the power supply line, wherein a resistance of the resistors in each of the protective elements is lower than a resistance of resistors in a first adjacent protective element on a side of the pad, and is higher than a resistance of resistors in a second adjacent protective element on a side of the internal circuit.
